(19) United States
(12) Patent Application Publication
(10) Pub. No.: US 2026/0271359 A1
(43) Pub. Date: Sep. 10, 2026

(54) SEMICONDUCTOR STRUCTURE AND METHODS OF FORMING THE SAME

(71) Applicant: NANYA TECHNOLOGY CORPORATION, New Taipei City (TW)

(72) Inventors: Yen-Ho CHU, New Taipei City (TW); Weng Yiang THAM, New Taipei City (TW)

(21) Appl. No.: 19/069,238

(22) Filed: Mar. 4, 2025

(51) Int. Cl. H10D 62/60; H10D 30/01; H10D 30/60; H10D 62/00; H10D 62/10; H10D 62/13

(52) U.S. Cl. CPC H10D 62/60; H10D 30/022; H10D 30/601; H10D 62/021; H10D 62/124; H10D 62/151

(57) ABSTRACT

The disclosure provides a method of forming a semiconductor structure, including forming a gate structure on a substrate, depositing a first dielectric material on the gate structure, performing a first implantation process to implant the substrate with a uniform top surface to form a first doping region in the substrate, performing a second implantation process to implant the substrate with the uniform top surface to form a second doping region in the substrate, depositing a second dielectric material on the first dielectric material, etching a portion of the first dielectric material, the second dielectric material and the substrate to form recesses in the substrate, performing a third implantation process to implant the recesses to form a third doping region in the substrate, and performing an anneal process.

### BACKGROUND

### Field of Invention

The present disclosure relates to a semiconductor structure and a method of forming the same.

### Description of Related Art

Due to semiconductor structure length scaling, implantation process are adopted to reduce hot carrier effect and punch through effect. However, the distribution and the depth of the implantation may be affected by a little bit recesses on the substrate, thereby influencing the performance stability of the semiconductor structure.

Therefore, a method of forming uniform distribution and depth of the implantation in the art is important.

### SUMMARY

The disclosure provides a method of forming a semiconductor structure, including forming a gate structure on a substrate, depositing conformally a first dielectric material on the gate structure and the substrate, performing a first implantation process to implant the substrate with a first doping species to form a first doping region in the substrate, wherein a top surface of the substrate is uniform. The method further includes performing a second implantation process to implant the substrate with a second doping species opposite to the first doping species to form a second doping region in the substrate, wherein the top surface of the substrate is uniform. The method further includes depositing a second dielectric material on the first dielectric material, etching a portion of the first dielectric material, the second dielectric material and the substrate to form recesses in the substrate, performing a third implantation process to implant the recesses in the substrate with a third doping species to form a third doping region in the substrate, wherein the third doping species is the same species as the second doping species, and performing an anneal process.

The disclosure provides a semiconductor structure, including a gate structure, spacers, a second dielectric layer, recesses, a first doping region, a second doping region and a third doping region. The gate structure is on the substrate. Each of the spacers includes a first portion along sidewalls of the gate structure and a second portion on the substrate and connected to an end of the first portion. The second dielectric layer is on the spacers and adjacent the first portion and the second portion. The recesses are exposed in a top portion of the substrate and laterally surrounding the gate structure, the spacers and the second dielectric layer. The first doping region with a first doping species is in the substrate, including a width between a top surface and a bottom surface of the first doping region in a range from 18.2 to 33.8 nm, a distance between the top surface of the first doping region and a top surface of the substrate in a range from 16.1 to 23.9 nm, a distance between the bottom surface of the first doping region and the top surface of the substrate in a range from 42.1 to 49.9 nm and a highest doping concentration at a depth below the top surface of the substrate in a range from 30 to 36 nm. The second doping region with a second doping species opposite to the first doping species in the substrate below the second portion, including a width between a top surface and a bottom surface of the second doping region in a range from 1.6 to 2.8 nm, a distance between the top surface of the second doping region and the top surface of the substrate in a range from 1.6 to 2.2 nm, a distance between the bottom surface of the second doping region and the top surface of the substrate in a range from 3.8 to 4.4 nm and a highest doping concentration at a depth below the top surface of the substrate in a range from 2.75 to 3.25 nm. The third doping region with a third doping species in the substrate below the recesses, wherein the third doping region is overlapping partially with the first doping region.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIGS. 1-7 are cross-section views of a manufacturing method of forming a semiconductor device at different stages according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

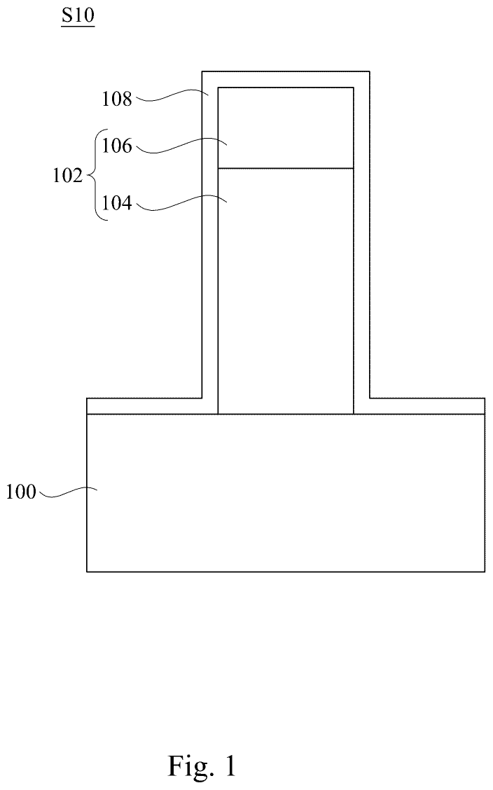

Referring to FIG. 1, the method begins from step S10. A substrate 100 is provided. A gate structure 102 is formed on the substrate 100. The gate structure 102 includes a conductive stack 104 and a cap layer 106 on the conductive stack 104. The conductive stack 104 may be single layer, double layer or multi-layer, and a material of the conductive stack 104 may be polysilicon, copper (Cu), tungsten (W), titanium (Ti) or the like. In some embodiments, the conductive stack 104 may include a polysilicon and a metal layer on the polysilicon. In some embodiments, the gate structure 102 is high-k metal gate (HKMG), an additional high-k dielectric layer (not shown), such as HfO₂, may be formed between the substrate 100 and the conductive stack 104 of the gate structure 102. In some embodiments, a material of the cap layer 106 may include silicon nitride.

After the formation of the gate structure 102, a first dielectric material 108 is deposited conformally on the substrate 100 and the gate structure 102. The first dielectric material 108 may extend along a top surface and sidewalls of the gate structure 102 and a top surface of the substrate 100. The first dielectric material 108 may be formed by any suitable deposition process, such as chemical vapor deposition (CVD), atomic layer deposition (ALD), physical vapor deposition (PVD) or the like. In some embodiments, a material of the first dielectric material 108 may include silicon oxide, silicon carbide, silicon nitride, silicon oxynitride, low-k dielectric material and/or any suitable insulating material to protect the gate structure 102.

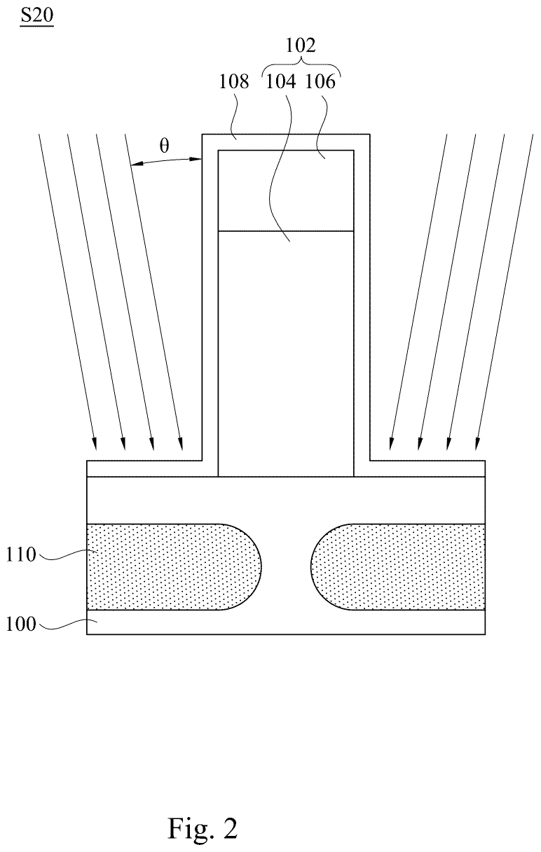

Referring to FIG. 2, the method goes to step S20. A first implantation process, such as halo implantation process, is performed to implant the substrate 100 with a first doping species through the first dielectric material 108 and form first doping regions 110 in the substrate 100. In some embodiments, a photoresist layer or a hard mask layer (not shown) may be formed on the gate structure 102, and prevent the gate structure 102 from being implanted during the first implantation process. The halo implantation process with angled implantation causes the resulting first doping regions 110 laterally extending a distance to areas in the substrate 100 below the gate structure 102. The halo implantation process may be performed with an angle θ from 12° to 22° to the sidewalls of the gate structure 102. In some embodiments, a doping concentration of the first doping species of the first doping regions 110 may be in a range from 1.0 E14 to 8.0 E14 cm².

It should be noticed that a top surface of the substrate 100 remains flat and/or uniform without any additional etching process, the distribution and the depth of the first doping regions 110 may be uniform. In addition, the first dielectric material 108 along the sidewalls of the gate structure 102 and the top surface of the substrate 100 may be in L-shape instead of an irregular corner, resulting in the uniform distribution of the first doping regions 110. In some embodiments, the semiconductor structure with n-type metal-oxide-semiconductor field effect transistors (NMOSFET), the first doping species may include p-type dopants, such as boron (B). In some embodiments, the semiconductor structure with p-type metal-oxide-semiconductor field effect transistors (PMOSFET), the first doping species may include n-type dopants, such as phosphorus (P).

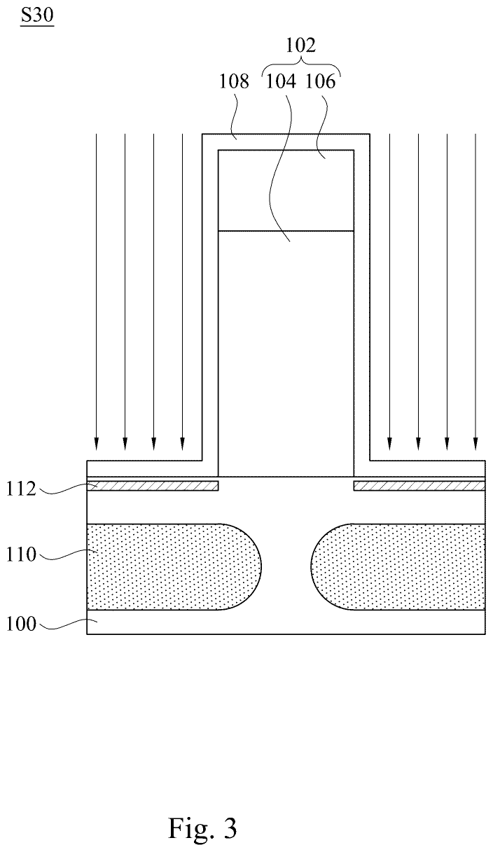

Referring to FIG. 3, the method goes to step S30. A second implantation process, such as light doped drain (LDD) implantation process, is performed to implant the substrate 100 with a second doping species opposite to the first doping species through the first dielectric material 108 and form second doping regions 112 in the substrate 100. The second doping regions 112 in the substrate 100 include a distribution and a doping species of the implantation different from the first doping regions 110. In some embodiments, a photoresist layer or a hard mask layer (not shown) may be formed on the gate structure 102, and prevent the gate structure 102 from being implanted during the second implantation process. The light doped drain implantation process may be performed vertically to the substrate 100. The gate structure 102 may be served as a mask, so that the second doping region 112 may not be located below the gate structure 102. As the result, the second doping regions 112 may distribute adjacent the top surface of the substrate 100 around the gate structure 102. In some embodiments, a doping concentration of the second doping species of the second doping region 112 may be in a range from 1.0 E15 to 6.0 E15 cm².

It should be noticed that the top surface of the substrate 100 remains flat and/or uniform without any additional etching process, the likelihood of the lateral scatter during the light doped drain implantation process may be reduced, thereby achieving shallower junction without lateral scatter. In some embodiments, the semiconductor structure with n-type metal-oxide-semiconductor field effect transistors (NMOSFET), the second doping species may include n-type dopants, such as phosphorus (P). In some embodiments, the semiconductor structure with p-type metal-oxide-semiconductor field effect transistors (PMOSFET), the second doping species may include p-type dopants, such as boron (B).

The halo implantation process and the light doped drain implantation process are adopted to prevent hot carrier effect and punch through effect. During the operation of the halo implantation process and the light doped drain implantation process as described in FIGS. 2-3 of the present disclosure, the top surface of the substrate 100 is flat and/or uniform without the additional etching process, resulting in the uniform distribution and the depth of the dopants, further improving the current between drain and source (IDs) stability. Furthermore, the light doped drain implantation process is performed to such a flat and/or uniform surface of the substrate 100 may achieve shallower junction without lateral scatter.

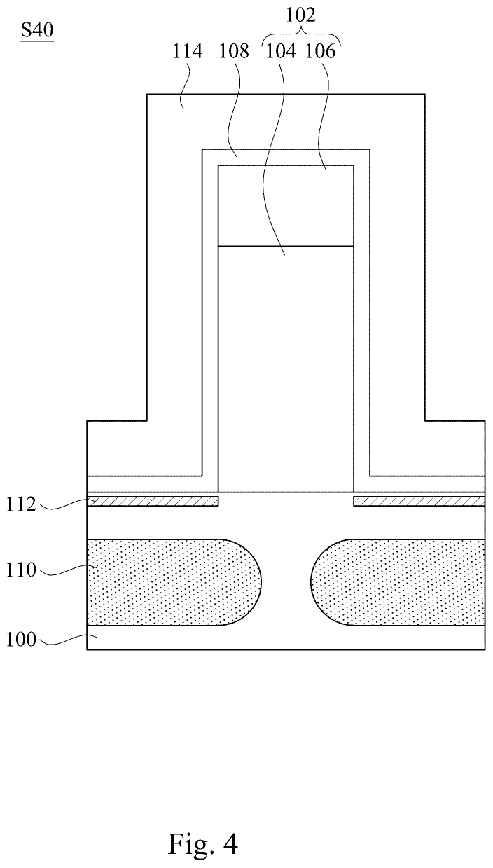

Referring to FIG. 4, the method goes to step S40. A second dielectric material 114 is deposited conformally on the first dielectric material 108. The second dielectric material 114 may overly the first dielectric material 108 and the gate structure 102. The second dielectric material 114 may be used to define a distance from the sidewalls of the gate structure 102 outwardly for following source/drain implantation. The distance for the following source/drain implantation may be various depend on the requirement of the process. The second dielectric material 114 may be formed by any suitable deposition process, such as chemical vapor deposition (CVD), atomic layer deposition (ALD), physical vapor deposition (PVD) or the like. In some embodiments, the second dielectric material 114 may include silicon oxide, silicon nitride, silicon oxynitride, fluoride-doped silicate glass (FSG), a high-k dielectric material and/or any suitable dielectric material.

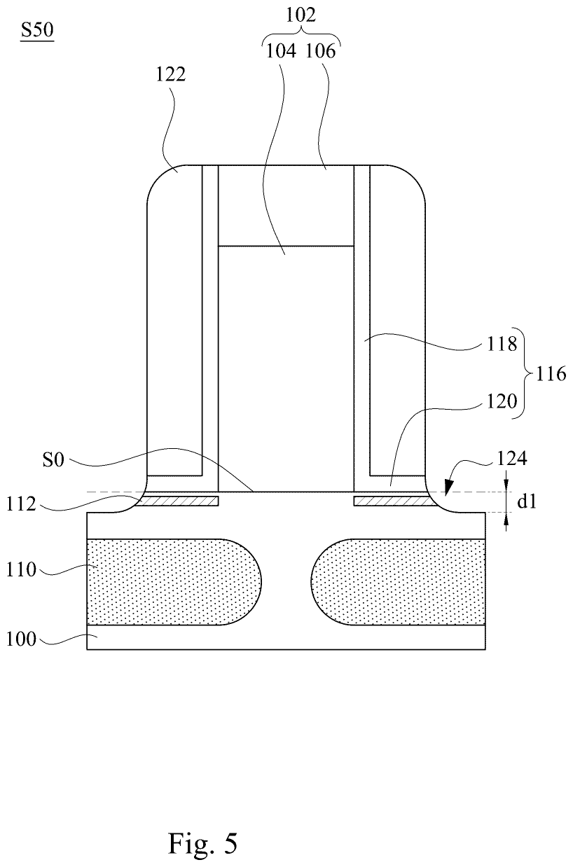

Referring to FIG. 5, the method goes to step S50. Etching process is performed to remove a portion of the first dielectric material 108 (as shown in FIG. 4), the second dielectric material 114 (as shown in FIG. 4) and the substrate 100 to form recesses 124 exposed in the top portion of the substrate 100. Specifically, a lateral portion of the first dielectric material 108 and the second dielectric material 114 above the gate structure 102 are removed to expose the top surface of the gate structure 102, and another lateral portion of the first dielectric material 108 and the second dielectric material 114 on the substrate 100 are removed partially to expose a portion of the top surface of the substrate 100, then followed by a formation of the recesses 124 in the substrate 100 with the exposed top surface. The etching process may be performed by any suitable process, such as dry etching and/or wet etching. In some embodiments, the top surface of the gate structure 102 is coplanar with a top surface of the remaining first dielectric material 108. In some embodiments, the recesses 124 may have a depth d1 from the top surface S0 of the substrate 100, and the depth d1 is in a range from 6 nm to 10 nm.

The remaining first dielectric material 108 may be referred as spacers 116. Each of the spacers 116 includes a first portion 118 along the sidewalls of the gate structure 102 and a second portion 120 along the top surface S0 of the substrate 100 and connected to an end of the first portion 118. In some embodiments, the first portions 118 and the second portions 120 are in L-shape. The remaining second dielectric material 114 may be referred as second dielectric layer 122. The second dielectric layer 122 on the spacers 116 and adjacent the first portions 118 and the second portions 120 of the spacers 116. Further, the second dielectric layer 122 may be surrounding laterally the gate structure 102 and the first portions 118 of the spacers 116.

After the etching process is performed, the recesses 124 may be surrounding laterally the gate structure 102, the spacers 116 and the second dielectric layer 122 in the top portion of the substrate 100. Due to the second doping regions 112 located near the top surface S0 of the substrate 100, the formation of the recesses 124 may further removes a portion of the second doping regions 112, so that the remaining second doping regions 112 may be located below the second portions 120 of the spacers 116.

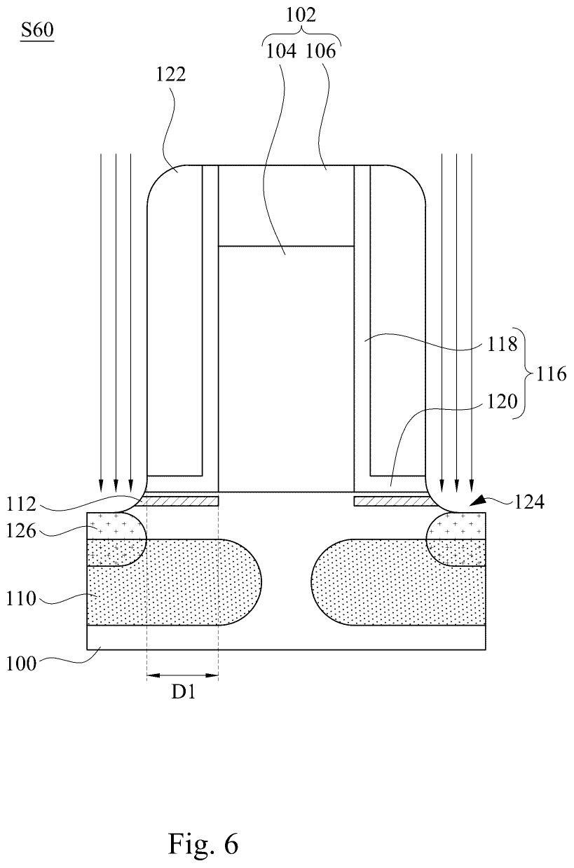

Referring to FIG. 6, the method goes to step S60. A third implantation process, such as source/drain implantation process, is performed to implant the recesses 124 in the substrate 100 with a third doping species same as the second doping species and form third doping regions 126 in the substrate 100. The second dielectric layer 122 and the gate structure 102 may be served as a protecting layer that prevents the area below the second dielectric layer 122 and the gate structure 102 from being implanted by source/drain implantation. The second dielectric layer 122 may further define the distance D1 to determine the lateral distance between the sidewalls of the gate structure 102 and the third doping region 126. The distance D1 may be various depend on the requirement of the process. The third doping regions 126 may be distributed in the substrate 100 below the recesses 124 and surrounding laterally the gate structure 102, the spacers 116 and the second dielectric layer 122. In some embodiments, a doping concentration of the third doping species of the third doping regions 126 may be in a range from 2.0 E15 to 9.0 E15 cm².

It should be noticed that the substrate 100 through once etching process (as described in FIG. 5) may include the recesses 124 with slightly uniform bottom surfaces, which is benefit for the depth of the source/drain implantation process. In some embodiments, the semiconductor structure with n-type metal-oxide-semiconductor field effect transistors (NMOSFET), the third doping species may include n-type dopant, such as phosphorus (P). In some embodiments, the semiconductor structure with p-type metal-oxide-semiconductor field effect transistors (PMOSFET), the third doping species may include p-type dopant, such as boron (B).

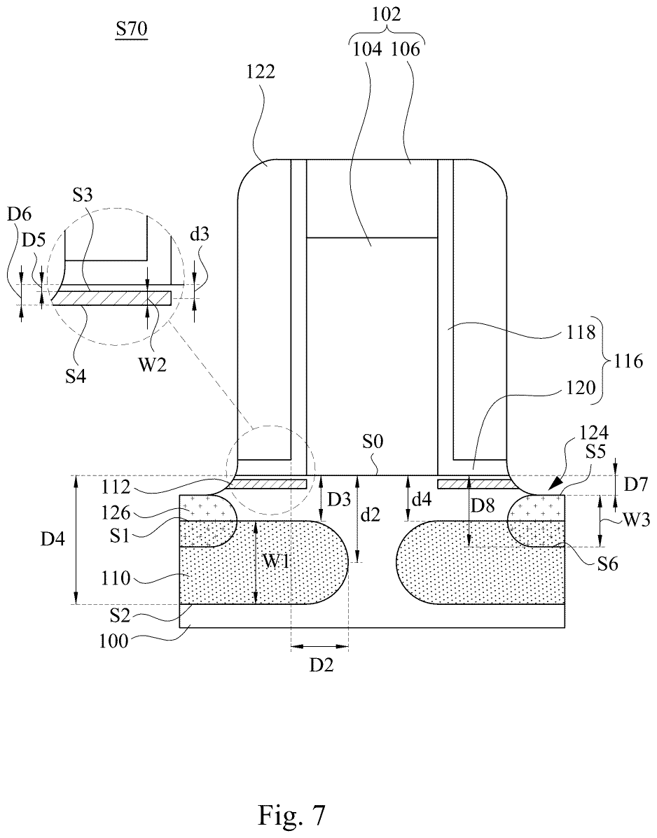

Referring to FIG. 7, the method goes to step S70. An anneal process is performed. After the anneal process, the first doping regions 110 may have a top surface S1 and a bottom surface S2, and a width W1 is between the top surface S1 and the bottom surface S2 of the first doping regions 110. In some embodiments, for example, the width W1 is in a range of from 18.2 to 33.8 nm. The first doping regions 110 have a distance D3 between the top surface S1 of the first doping regions 110 and the top surface S0 of the substrate 100 in a range from 16.1 to 23.9 nm. The first doping regions 110 have a distance D4 between the bottom surface S2 of the first doping regions 110 and the top surface S0 of the substrate 100 in a range from 42.1 to 49.9 nm. Each of the first doping regions 110 has a highest doping concentration at a depth d2 below the top surface S0 of the substrate 100, which the depth d2 is in a range from 30 to 36 nm. The doping concentration of the first doping regions 110 is gradually decreased from the depth d2 to the top surface S1 of the first doping regions 110, and the doping concentration of the first doping regions 110 is gradually decreased from the depth d2 to the bottom surface S2 of the first doping regions 110. In some embodiments, for example, the highest doping concentration of the first doping regions 110 is at a depth d2 of 33 nm from the top surface S0 of the substrate 100, and the doping distribution of the first doping regions 110 may be distributed at a depth in a range of 33±13 nm from the top surface S0 of the substrate 100. In other words, the distance D3 between the top surface S1 of the first doping regions 110 and the top surface S0 of the substrate 100 is about 20 nm, and the distance D4 between the bottom surface S2 of the first doping regions 110 and the top surface S0 of the substrate 100 is about 46 nm. The doping concentration of the first doping regions 110 is gradually decreased from the depth d2 of 33 nm from the top surface S0 of the substrate 100 to the top surface S1 of the first doping regions 110 (e.g. at the distance D3 of 20 nm from the top surface S0 of the substrate 100), and the doping concentration of the first doping regions 110 is gradually decreased from the depth d2 of 33 nm from the top surface S0 of the substrate 100 to the bottom surface S2 of the first doping regions 110 (e.g. at the distance D4 of 46 nm from the top surface S0 of the substrate 100). Further, the first doping regions 110 extend the distance D2 to the area below the gate structures 102 due to the halo implantation process with angled implantation. For example, the distance D2 is in a range from 4.3 nm to 18.6 nm from sidewalls of the first portions 118 of the spacers 116.

After the anneal process, the second doping regions 112 may have a top surface S3 and a bottom surface S4, and a width W2 is between the top surface S3 and the bottom surface S4 of the second doping regions 112. In some embodiments, for example, the width W2 is in a range of from 1.6 to 2.8 nm. The second doping regions 112 have a distance D5 between the top surface S3 of the second doping regions 112 and the top surface S0 of the substrate 100 in a range from 1.6 to 2.2 nm. The second doping regions 112 have a distance D6 between the bottom surface S4 of the second doping regions 112 and the top surface S0 of the substrate 100 in a range from 3.8 to 4.4 nm. Each of the second doping regions 112 has a highest doping concentration at a depth d3 below the top surface S0 of the substrate 100, which the depth d3 is in a range from 2.75 to 3.25 nm. The doping concentration of the second doping regions 112 is gradually decreased from the depth d3 to the top surface S3 of the second doping regions 112, and the doping concentration of the second doping regions 112 is gradually decreased from the depth d3 to the bottom surface S4 of the second doping regions 112. In some embodiments, for example, the highest doping concentration of the second doping regions 112 is at a depth d3 of 3 nm from the top surface S0 of the substrate 100, and the doping distribution of the second doping regions 112 may be distributed at a depth in a range of 3±1.1 nm from the top surface S0 of the substrate 100. In other words, the distance D5 between the top surface S3 of the second doping regions 112 and the top surface S0 of the substrate 100 is about 1.9 nm, and the distance D6 between the bottom surface S4 of the second doping regions 112 and the top surface S0 of the substrate 100 is about 4.1 nm. The doping concentration of the second doping regions 112 is gradually decreased from the depth d3 of 3 nm from the top surface S0 of the substrate 100 to the top surface S3 of the second doping regions 112 (e.g. at the distance D5 of 1.9 nm from the top surface S0 of the substrate 100), and the doping concentration of the second doping regions 112 is gradually decreased from the depth d3 of 3 nm from the top surface S0 of the substrate 100 to the bottom surface S4 of the second doping regions 112 (e.g. at the distance D6 of 4.1 nm from the top surface S0 of the substrate 100).

After the anneal process, the third doping regions 126 may have a top surface S5 and a bottom surface S6, and a width W3 is between the top surface S5 and the bottom surface S6 of the third doping regions 126. In some embodiments, for example, the width W3 is in a range of from 8 to 24 nm. The third doping regions 126 have a distance D7 between the top surface S5 of the third doping regions 126 and the top surface S0 of the substrate 100 in a range from 7.5 to 15.5 nm. The third doping regions 126 have a distance D8 between the bottom surface S6 of the third doping regions 126 and the top surface S0 of the substrate 100 in a range from 23.5 to 31.5 nm. Each of the third doping regions 126 has a highest doping concentration at a depth d4 below the top surface S0 of the substrate 100, which the depth d4 is in a range from 16 to 20 nm. The doping concentration of the third doping regions 126 is gradually decreased from the depth d4 to the top surface S5 of the third doping regions 126, and the doping concentration of the third doping regions 126 is gradually decreased from the depth d4 to the bottom surface S6 of the third doping regions 126. In some embodiments, for example, the highest doping concentration of the third doping regions 126 is at a depth d4 of 18 nm from the top surface S0 of the substrate 100, and the doping distribution of the third doping regions 126 may be distributed at a depth in a range of 18±8 nm from the top surface S0 of the substrate 100. In other words, the distance D7 between the top surface S5 of the third doping regions 126 and the top surface S0 of the substrate 100 is about 10 nm, and the distance D8 between the bottom surface S6 of the third doping regions 126 and the top surface S0 of the substrate 100 is about 26 nm. The doping concentration of the third doping regions 126 is gradually decreased from the depth d4 of 18 nm from the top surface S0 of the substrate 100 to the top surface S5 of the third doping regions 126 (e.g. at the distance D7 of 10 nm from the top surface S0 of the substrate 100), and the doping concentration of the third doping regions 126 is gradually decreased from the depth d4 of 18 nm from the top surface S0 of the substrate 100 to the bottom surface S6 of the third doping regions 126 (e.g. at the distance D8 of 26 nm from the top surface S0 of the substrate 100). The first doping regions 110 and the third doping regions 126 are overlapping partially.

The first doping regions 110 including the first doping species, the second doping regions 112 including the second doping species opposite to the first doping species, and the third doping regions 126 include the third doping species the same as the second doping species. In some embodiments, the semiconductor structure with n-type metal-oxide-semiconductor field effect transistors (NMOSFET), the first doping regions 110, the second doping regions 112 and the third doping regions 126 may include p-type dopant, n-type dopant, and n-type dopant respectively. On the other hand, the semiconductor structure with p-type metal-oxide-semiconductor field effect transistors (PMOSFET), the first doping regions 110, the second doping regions 112 and the third doping regions 126 may include n-type dopant, p-type dopant, and p-type dopant respectively.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of forming a semiconductor structure, comprising:
forming a gate structure on a substrate;
depositing conformally a first dielectric material on the gate structure and the substrate;
performing a first implantation process to implant the substrate with a first doping species to form a first doping region in the substrate, wherein a top surface of the substrate is uniform;
performing a second implantation process to implant the substrate with a second doping species opposite to the first doping species to form a second doping region in the substrate, wherein the top surface of the substrate is uniform;
depositing a second dielectric material on the first dielectric material;
etching a portion of the first dielectric material, the second dielectric material and the substrate to form recesses in the substrate;
performing a third implantation process to implant the recesses in the substrate with a third doping species to form a third doping region in the substrate, wherein the third doping species is the same species as the second doping species; and
performing an anneal process.

2. The method of claim 1, wherein the first implantation process comprises HALO implantation with an angled implantation, and the second implantation process comprises light doped drain (LDD) implantation.

3. The method of claim 2, wherein the angled implantation is at an angle between 12° and 22° to sidewalls of the gate structure.

4. The method of claim 3, wherein the first doping region extends to an area below the gate structure.

5. The method of claim 1, wherein a doping concentration of the first doping species of the first doping region is from 1.0 E14 to 8.0 E14 cm².

6. The method of claim 1, wherein a doping concentration of the second doping species of the second doping region is from 1.0 E15 to 6.0 E15 cm².

7. The method of claim 1, wherein a doping concentration of the third doping species of the third doping region is from 2.0 E15 to 9.0 E15 cm².

8. The method of claim 1, wherein the third implantation process comprises source/drain implantation.

9. The method of claim 1, wherein etching the portion of the first dielectric material, the second dielectric material and the substrate to form the recesses in the substrate comprises:
removing a lateral portion of the first dielectric material and the second dielectric material above a top surface of the gate structure and removing partially another lateral portion of the first dielectric material and the second dielectric material on the substrate, such that the top surface of the gate structure is exposed.

10. The method of claim 1, wherein etching the portion of the first dielectric material and the second dielectric material to form the recesses in the substrate further comprises removing a portion of the second doping region.

11. A semiconductor structure, comprising:
a gate structure on a substrate;
spacers, each of the spacers comprising:
a first portion along sidewalls of the gate structure; and
a second portion on the substrate and connected to an end of the first portion;
a second dielectric layer on the spacers and adjacent the first portions and the second portions;
recesses exposed in a top portion of the substrate and laterally surrounding the gate structure, the spacers and the second dielectric layer;
a first doping region with a first doping species in the substrate, comprising:
a width between a top surface and a bottom surface of the first doping region in a range from 18.2 to 33.8 nm;
a distance between the top surface of the first doping region and a top surface of the substrate in a range from 16.1 to 23.9 nm;
a distance between the bottom surface of the first doping region and the top surface of the substrate in a range from 42.1 to 49.9 nm; and
a highest doping concentration at a depth below the top surface of the substrate in a range from 30 to 36 nm;
a second doping region with a second doping species opposite to the first doping species in the substrate below the second portion, comprising:
a width between a top surface and a bottom surface of the second doping region in a range from 1.6 to 2.8 nm;
a distance between the top surface of the second doping region and the top surface of the substrate in a range from 1.6 to 2.2 nm;
a distance between the bottom surface of the second doping region and the top surface of the substrate in a range from 3.8 to 4.4 nm; and
a highest doping concentration at a depth below the top surface of the substrate in a range from 2.75 to 3.25 nm; and
a third doping region with a third doping species in the substrate below the recesses, wherein the third doping region is overlapping partially with the first doping region.

12. The semiconductor structure of claim 11, wherein a doping concentration of the first doping region is gradually decreased from the depth to the top surface of the first doping region; and wherein the doping concentration of the first doping region is gradually decreased from the depth to the bottom surface of the first doping region.

13. The semiconductor structure of claim 11, wherein the recesses are in a range from 6 nm to 10 nm from the top surface of the substrate.

14. The semiconductor structure of claim 13, wherein the third doping region comprises:
a width between a top surface and a bottom surface of the third doping region in a range from 8 to 24 nm;
a distance between the top surface of the third doping region and the top surface of the substrate in a range from 7.5 to 15.5 nm;
a distance between the bottom surface of the third doping region and the top surface of the substrate in a range from 23.5 to 31.5 nm; and
a highest doping concentration at a depth below the top surface of the substrate in a range from 16 to 20 nm.

15. The semiconductor structure of claim 11, wherein the first portion and the second portion are in L-shape.

16. The semiconductor structure of claim 11, wherein the semiconductor structure comprises NMOS transistor, the first doping species comprising p-type dopant, the second doping species comprising n-type dopant, and the third doping species comprising n-type dopant.
